(19) United States
(12) Patent Application Publication
(10) Pub. No.: US 2026/0353985 A1
(43) Pub. Date: Nov. 5, 2026

(54) DISPLAY DEVICE

(71) Applicant: LG Display Co., Ltd., Seoul (KR)

(72) Inventors: Byonghoo Kim, Paju-si (KR); JuHyuk Kim, Goyang-si (KR); WonJeong Shin, Goyang-si (KR); HyoKyeong Son, Paju-si (KR); Minwan Kim, Paju-si (KR)

(21) Appl. No.: 19/658,678

(22) Filed: Apr. 26, 2026

(30) Foreign Application Priority Data
Apr. 30, 2025 (KR) 10-2025-0057341

(51) Int. Cl. H10K 59/80; G06F 3/041; G06F 3/044; H10K 59/40; H10K 102/00

(52) U.S. Cl. CPC H10K 59/873; G06F 3/0412; G06F 3/0446; H10K 59/40; H10K 2102/311

(57) ABSTRACT

A display device includes a substrate having a display area and a non-display area, and a plurality of light emitting elements disposed in the display area. An encapsulation part covers the light emitting elements, and a touch sensing unit is disposed on the encapsulation part. A touch planarization layer is disposed on the touch electrodes, and a protective layer is disposed on the touch planarization layer. A lower partition wall adhesive layer is disposed in the non-display area to surround the display area, is disposed on the same layer as the touch planarization layer, and is spaced apart from the touch planarization layer. An upper partition wall adhesive layer is disposed on the lower partition wall adhesive layer. The lower partition wall adhesive layer includes a plurality of protrusion portions protruding upward, and the upper partition wall adhesive layer overlaps the protrusion portions in a thickness direction.

### CROSS REFERENCE TO RELATED APPLICATION

This application claims priority from and the benefit of Korean Patent Application No. 10-2025-0057341, filed on Apr. 30, 2025, which is hereby incorporated by reference for all purposes as if fully set forth herein.

### BACKGROUND

### Field

Embodiments of the invention relate generally to a display device, and more particularly, to a display device capable of reducing stress and suppressing damage to a touch sensor when a bezel is bent.

### Discussion of the Background

In general, a display device is widely used as a display screen of various electronic devices such as a mobile communication terminal, an electronic notebook, an electronic book, a Portable Multimedia Player (PMP), a navigation, a Ultra Mobile PC (UMPC), a mobile phone, a smart phone, a tablet PC, a watch phone, an electronic pad, a wearable device, a watch phone, a portable information device, a navigation, a vehicle control display device, a television, a notebook, and a monitor.

Recently, research and development have been conducted on a display device capable of realizing a maximum screen by reducing a bezel area in which an image is not displayed at the same size of a display panel.

The above information disclosed in this Background section is only for understanding of the background of the inventive concepts, and, therefore, it may contain information that does not constitute prior art.

### SUMMARY

The present disclosure provides a display device capable of minimizing a width of a bezel area and reducing stress caused by a micro coating layer when a bezel is bent.

The present disclosure provides a display device capable of suppressing lateral moisture permeation and crack generation.

The present disclosure provides a display device capable of reducing stress generated in a bending area and improves reliability.

Additional features of the inventive concepts will be set forth in the description which follows, and in part will be apparent from the description, or may be learned by practice of the inventive concepts.

According to an embodiment of the present disclosure, a display device includes a substrate including a display area and a non-display area, a plurality of light emitting elements disposed in the display area of the substrate, an encapsulation part disposed to cover the plurality of light emitting elements, a touch sensing unit disposed on the encapsulation part and including a plurality of touch electrodes, a touch planarization layer disposed on the plurality of touch electrodes, a protective layer disposed on the touch planarization layer, a lower partition wall adhesive layer disposed in the non-display area so as to surround the display area, the lower partition wall adhesive layer being disposed on the same layer as the touch planarization layer while being spaced apart from the touch planarization layer, and an upper partition wall adhesive layer disposed on the lower partition wall adhesive layer, wherein the lower partition wall adhesive layer includes a plurality of protrusion portions protruding upward, and the upper partition wall adhesive layer overlaps the plurality of protrusion portions in a thickness direction.

The protective layer may extend from the display area to the non-display area and is disposed so that at least a portion of the protective layer is in direct contact with a side surface of the lower partition wall adhesive layer.

The lower partition wall adhesive layer may further include a lower layer, and the plurality of protrusion portions are disposed on a top surface of the lower layer, and the protective layer may be in direct contact with at least a portion of the plurality of protrusion portions. The upper partition wall adhesive layer may be disposed to cover all the top surfaces and side surfaces of the plurality of protrusion portions and the lower layer.

The upper partition wall adhesive layer may be disposed on the lower partition wall adhesive layer and on a top surface of the protective layer so as to cover a contact surface between the protective layer and the lower partition wall adhesive layer.

A work of adhesion of the upper partition wall adhesive layer may be less than a work of adhesion of the lower partition wall adhesive layer.

The work of adhesion of the lower partition wall adhesive layer may be in a range of about 60 to about 80 mJ/m², and the work of adhesion of the upper partition wall adhesive layer may be in a range of about 30 to about 50 mJ/m².

An elastic modulus of the lower partition wall adhesive layer may be in a range of about 1.5 to about 2.0 GPa, and an elastic modulus of the upper partition wall adhesive layer may be in a range of about 6.0 to about 8.0 GPa.

The non-display area may include a first non-display area adjacent to the display area, a bending area extending from the first non-display area, and a second non-display area extending from one side of the bending area, and the lower partition wall adhesive layer and the upper partition wall adhesive layer may be disposed between the bending area and the display area.

The touch sensing unit may include: a touch buffer layer disposed on the encapsulation part; a bridge electrode disposed on the touch buffer layer; a touch interlayer insulating layer disposed on the bridge electrode; and a touch electrode disposed on the touch interlayer insulating layer, and the lower partition wall adhesive layer may overlap the touch buffer layer and the touch interlayer insulating layer in a thickness direction.

The display device may further include: a plurality of routing lines connecting the plurality of touch electrodes to a plurality of touch pads disposed in the second non-display area. The lower partition wall adhesive layer may be disposed on the plurality of routing lines.

The display device may further include: at least one dam which is disposed in the non-display area and configured to surround the display area, in which the encapsulation part includes a first inorganic encapsulation layer, an organic encapsulation layer disposed on the first inorganic encapsulation layer, and a second inorganic encapsulation layer disposed on the organic encapsulation layer, in which the first inorganic encapsulation layer and the second inorganic encapsulation layer are disposed on the dam, and in which the upper partition wall adhesive layer and the lower partition wall adhesive layer are disposed between the dam and the display area.

The upper partition wall adhesive layer may include a superhydrophobic material.

The lower partition wall adhesive layer may include a same material as the touch planarization layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view of a display device according to an embodiment of the present disclosure.

FIG. 2 is a schematic plan view illustrating an embodiment of the display device illustrated in FIG. 1.

FIG. 3 is a schematic cross-sectional view taken along line I-I′ of FIG. 2.

FIG. 4 is an enlarged schematic cross-sectional view of an area A of FIG. 3.

FIG. 5 is a schematic cross-sectional view of a display device according to another embodiment of the present disclosure.

FIGS. 6A, 6B, 6C, 6D, 6E and 6F are schematic cross-sectional views for explaining a method of manufacturing a display device according to an embodiment of the present disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

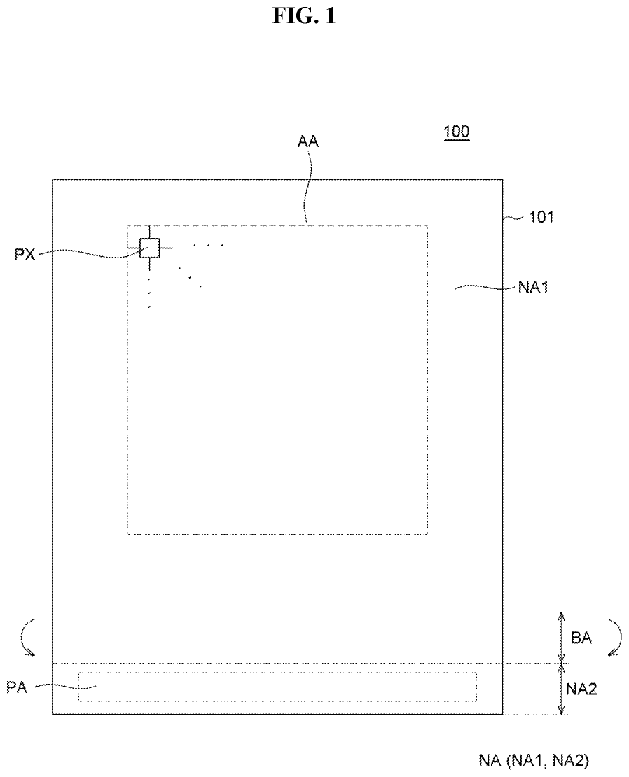

FIG. 1 is a schematic plan view of a display device according to an embodiment of the present disclosure.

In FIG. 1, for the convenience of description, among various components of the display device 100, a substrate 101 and a plurality of pixels PX are illustrated.

The substrate 101 may be a component configured to support various components included in the display device 100 and may include an insulating material. The substrate 101 may include a flexible material that can be bent. The substrate 101 may include a transparent insulating material. For example, the substrate 101 may include a plastic material such as polyimide (PI).

A plurality of gate lines and a plurality of data lines may be disposed to cross each other on the substrate 101. A plurality of pixels PX may be defined at intersections of a plurality of gate lines and a plurality of data lines. An area in which a plurality of pixels PX implementing an image is disposed may be referred to as a display area AA, and an area which is disposed outside the display area AA and in which a plurality of pixels PX is not disposed may be referred to as a non-display area NA.

A display unit configured to display an image and a circuit part configured to drive the display unit may be formed in the display area AA. For example, when the display device 100 is an organic light emitting display device, the display unit may include a light emitting element. When the display device 100 is a liquid crystal display device, the display unit may be configured to include a liquid crystal layer. Hereinafter, for convenience of description, it is assumed that the display device 100 is an organic light emitting display device, but it is not limited thereto.

The circuit part may include various transistors, capacitors, and lines configured to drive the light emitting element. For example, the circuit part may include various components such as a driving transistor, a switching transistor, a storage capacitor, a gate line, and a data line, but is not limited thereto.

The non-display area NA may be an area where no image is displayed and various lines, circuits, and the like for driving the display unit disposed in the display area AA are disposed.

The non-display area NA may be defined as an area surrounding the display area AA as illustrated in FIG. 1. However, the present disclosure is not limited thereto, and the non-display area NA may be defined as an area extending from the display area AA. In addition, the non-display area NA may be defined to extend from a plurality of sides of the display area AA.

In the non-display area NA, various ICs and driving circuits such as a gate driver IC and a data driver IC, and COF, an FPCB may be disposed. Further, a driving circuit referred to as a gate in panel (GIP) may be disposed in the non-display area NA.

The non-display area NA may include a first non-display area NA1 adjacent to the display area AA, a bending area BA extending from the first non-display area NA1, and a second non-display area NA2 extending from one side of the bending area BA.

Specifically, the first non-display area NA1 may be an area where no image is displayed and is disposed to surround the display area AA. The first non-display area NA1 may be an area in which various lines, driving ICs, and the like for driving a plurality of sub pixels disposed in the display area AA are disposed. The first non-display area NA1 in which no image is displayed may be a bezel area, but an embodiment of the present disclosure are not limited thereto.

A part of the non-display area NA may be bent in a bending direction, such as an arrow illustrated in FIG. 1. The area to be bent in this way may be referred to as a bending area BA. In other words, the bending area BA may be a part of the first non-display area NA1 extending from one side of the non-display area NA, and may be an area that is bent.

The pad part PA may be disposed in the second non-display area NA2 extending from one side of the bending area BA. The pad part PA may include a plurality of pad electrodes to which external modules are bonded.

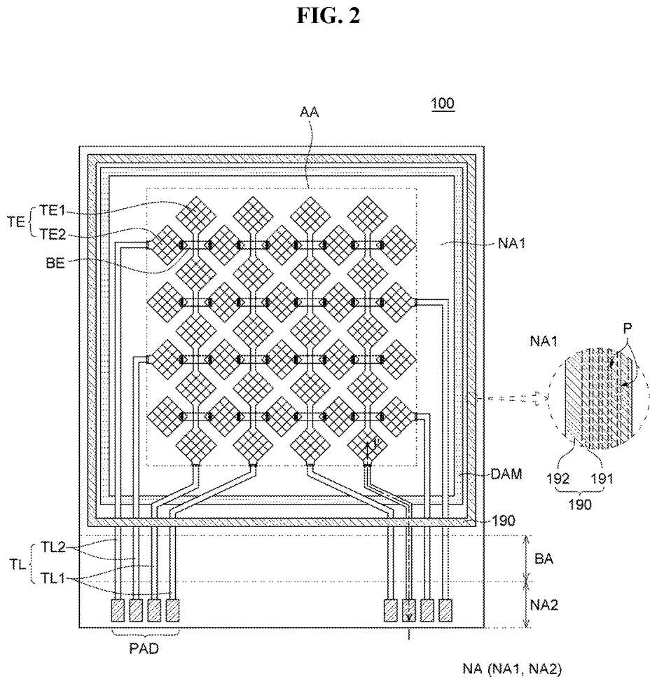

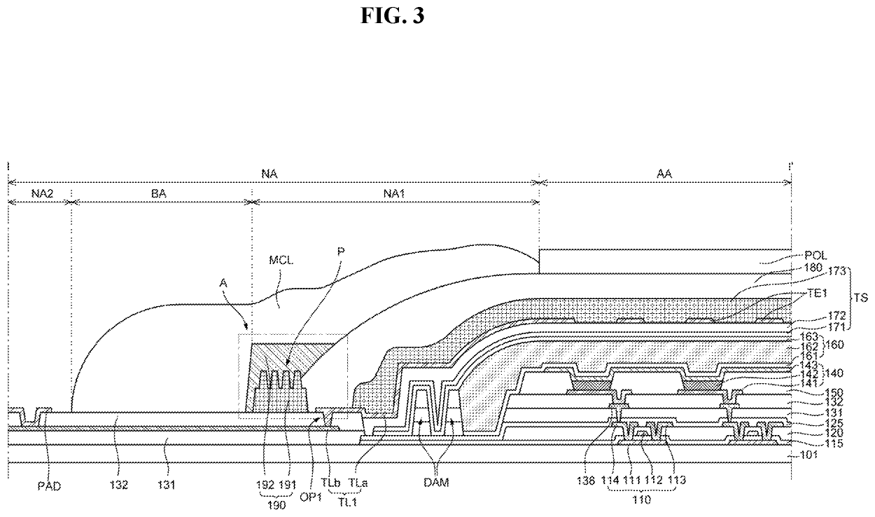

Hereinafter, the display device 100 will be described in more detail with reference to FIGS. 2 and 3 together.

FIG. 2 is a schematic plan view illustrating an embodiment of the display device illustrated in FIG. 1. FIG. 3 is a schematic cross-sectional view taken along line I-I′ of FIG. 2.

In the substrate 101, a thin film transistor 110 configured to drive each pixel may be disposed in the display area AA. The thin film transistor 110 may include an active layer 111, a gate electrode 112, a source electrode 113, and a drain electrode 114.

The active layer 111 may be disposed on the substrate 101. The active layer 111 may include polysilicon (p-Si), amorphous silicon (a-Si), or an oxide semiconductor, but is not limited thereto.

The gate insulating layer 115 may be disposed on the substrate 101 and the active layer 111. The gate insulating layer 115 may include silicon oxide (SiOₓ), silicon nitride (SiNₓ), or multiple layers thereof.

The gate electrode 112 may be disposed on the gate insulating layer 115. The gate electrode 112 may be disposed on the gate insulating layer 115 so as to overlap the active layer 111. The gate electrode 112 may include various conductive materials, such as magnesium (Mg), aluminum (Al), nickel (Ni), chromium (Cr), molybdenum (Mo), tungsten (W), gold (Au), or an alloy thereof, but is not limited thereto.

The interlayer insulating layer 120 may be disposed on the gate insulating layer 115 and the gate electrode 112. The interlayer insulating layer 120 may include silicon oxide (SiOₓ), silicon nitride (SiNₓ), or multiple layers thereof.

The source electrode 113 and the drain electrode 114 may be disposed on the interlayer insulating layer 120. The source electrode 113 and the drain electrode 114 may be electrically connected to the active layer 111 through contact holes formed in the gate insulating layer 115 and the interlayer insulating layer 120. The source electrode 113 and the drain electrode 114 may include various conductive materials, such as magnesium (Mg), aluminum (Al), nickel (Ni), chromium (Cr), molybdenum (Mo), tungsten (W), gold (Au), or an alloy thereof, but are not limited thereto.

A passivation layer 125 configured to insulate the thin film transistor 110 may be disposed on the source electrode 113 and the drain electrode 114. The passivation layer 125 may include an inorganic layer, for example, silicon oxide (SiOₓ), silicon nitride (SiNₓ), or multiple layers thereof.

The first planarization layer 131 may be disposed on the passivation layer 125. The first planarization layer 131 may protect the thin film transistor 110 and planarize an upper portion thereof. The first planarization layer 131 may include, for example, an organic insulating layer such as benzocyclobutene (BCB) or acrylic, but is not limited thereto.

The connection electrode 138 may be disposed on the first planarization layer 131. The connection electrode 138 may be electrically connected to the source electrode 113 or the drain electrode 114 through a contact hole included in the first planarization layer 131. The connection electrode 138 may include various conductive materials, such as magnesium (Mg), aluminum (Al), nickel (Ni), chromium (Cr), molybdenum (Mo), tungsten (W), gold (Au), or an alloy thereof, but is not limited thereto. The connection electrode 138 may include the same material as the source electrode 113 or the drain electrode 114.

The second planarization layer 132 may be disposed on the connection electrode 138. The second planarization layer 132 may protect the connection electrode 138 and planarize an upper portion thereof. For example, the second planarization layer 132 may include an organic insulating layer such as benzocyclobutene (BCB) or acrylic, but is not limited thereto. The second planarization layer 132 may include the same material as the first planarization layer 131.

The light emitting element 140 may be disposed on the second planarization layer 132. The light emitting element 140 may include an anode 141, an organic emission layer 142, and a cathode 143.

The anode 141 may be formed on the second planarization layer 132 to correspond to the emission area of each pixel PX. The anode 141 may be electrically connected to the drain electrode 114 of the thin film transistor 110 through the contact holes of the first planarization layer 131 and the second planarization layer 132. The anode 141 may include a metallic material.

When the display device 100 is a top emission type in which light emitted from the light emitting element 140 is emitted towards above the substrate 101 on which the light emitting element 140 is disposed, the anode 141 may further include a transparent conductive layer and a reflective layer on the transparent conductive layer. The transparent conductive layer may include a transparent conductive oxide such as ITO or IZO, and the reflective layer may include, for example, silver (Ag), aluminum (Al), gold (Au), molybdenum (Mo), tungsten (W), chromium (Cr), or an alloy thereof.

The bank layer 150 may be formed in the remaining area excluding the emission area. Accordingly, the bank layer 150 may expose the anode 141 corresponding to the emission area. The bank layer 150 may include an inorganic insulating material, such as silicon nitride (SiNₓ) or silicon oxide (SiOₓ), or an organic insulating material, such as benzocyclobutene-based resin, acrylic resin, or imide-based resin, but is not limited thereto.

A spacer may be further formed on the bank layer 150. The spacer may include the same material as the bank layer 150. The spacer may perform a function of preventing the damage to the light emitting element 140 which may be caused by a fine metal mask (FMM) used when the organic emission layer 142 is patterned.

The organic emission layer 142 may be disposed on the anode 141 exposed by the bank layer 150. The organic emission layer 142 may include a hole injection layer, a hole transport layer, an emission layer, an electron transport layer, and an electron injection layer. The organic emission layer 142 may have a single emission layer structure configured to emit light of a single color, or may have a structure including a plurality of emission layers configured to emit white light.

The cathode 143 may be disposed on the organic emission layer 142. The cathode 143 supplies electrons to the organic emission layer 142 so that the cathode may include a conductive material having a low work function. The cathode 143 may be formed as one layer over a plurality of sub pixels. In particular, the cathodes 143 of the plurality of sub pixels may be electrically connected to and integrated with each other.

The encapsulation part 160 may be disposed on the cathode 143. The encapsulation part 160 may protect the light emitting element 140 from moisture and oxygen. When the light emitting element 140 is exposed to moisture or oxygen, a pixel shrinkage phenomenon, in which the light emitting element 140 shrinks, may occur, or a dark spot may be generated in the emission area.

For example, the encapsulation part 160 may include a first inorganic encapsulation layer 161, an organic encapsulation layer 162 on the first inorganic encapsulation layer 161, and a second inorganic encapsulation layer 163 on the organic encapsulation layer 162. The first inorganic encapsulation layer 161 and the second inorganic encapsulation layer 163 may include an inorganic insulating layer.

For example, the first inorganic encapsulation layer 161 and the second inorganic encapsulation layer 163 may include an inorganic insulating material such as silicon nitride (SiNₓ), silicon oxide (SiOₓ), silicon oxynitride (SiON), or aluminum oxide (Al₂O₃). The organic encapsulation layer 162 may include an organic insulating layer. For example, the organic encapsulation layer 162 may include acrylic resin or epoxy resin.

The second inorganic encapsulation layer 163 may cover upper surfaces and side surfaces of the first inorganic encapsulation layer 161 and the organic encapsulation layer 162, and the second inorganic encapsulation layer 163 minimizes or blocks external moisture or oxygen from penetrating into the first inorganic encapsulation layer 161 and the organic encapsulation layer 162. In this case, the first inorganic encapsulation layer 161 and the second inorganic encapsulation layer 163 may block the penetration of moisture or oxygen, and the organic encapsulation layer 162 may serve to planarize the upper portion of the first inorganic encapsulation layer 161. However, the configuration of the encapsulation part 160 is not limited thereto.

A dam DAM which blocks the flow of the organic encapsulation layer 162 which configures the encapsulation part 160 may be disposed in the non-display area NA. Specifically, the dam DAM may be disposed in a closed curve shape surrounding the display area AA in the non-display area NA, the first inorganic encapsulation layer 161 and the second inorganic encapsulation layer 163 may be disposed on the dam DAM, and the flow of the organic encapsulation layer 162 may be prevented by the dam DAM.

The dam DAM may be formed to have a predetermined height or more to prevent the flow of the organic encapsulation layer 162. To this end, the dam DAM may include at least one or more layers made of an organic material. For example, the dam DAM may include a lower layer formed of the same material as the first planarization layer 131 and the second planarization layer 132, and an upper layer formed of the same material as the bank layer 150, but is not limited thereto. Although the drawing illustrates a configuration with two dams, one or three or more dams may be provided.

The touch sensing unit TS may be formed on the encapsulation part 160. Specifically, the touch sensing unit TS may include a touch buffer layer 171, a bridge electrode BE, a touch interlayer insulating layer 172, a plurality of touch electrodes TE including a first touch electrode TE1 and a second touch electrode TE2 intersecting each other, and a touch planarization layer 173, disposed on the encapsulation part 160.

The touch buffer layer 171 may be disposed on the encapsulation part 160. The touch buffer layer 171 may cover the dam DAM disposed in the non-display area NA. The touch buffer layer 171 may prevent a liquid chemical such as a developer or an etching solution used in the manufacturing process of the touch electrode TE formed on the touch buffer layer 171 or external moisture or foreign substances from penetrating into the light emitting element.

Although not illustrated in FIG. 3, a bridge electrode BE may be disposed on the touch buffer layer 171. The bridge electrode BE may be disposed in the display area AA, and electrically connect the second touch electrodes TE2 on the touch interlayer insulating layer 172.

In order to prevent a short circuit in an area where the first touch electrode TE1 and the second touch electrode TE2 intersect, the adjacent second touch electrode TE2 may be electrically connected through the bridge electrode BE. The bridge electrode BE may be disposed on a different layer from the first touch electrode TE1 and the second touch electrode TE2 and connected to an adjacent second touch electrode TE2 through a contact hole. The bridge electrode BE may intersect the first touch electrode TE1.

In this case, the contact hole may be formed through the touch interlayer insulating layer 172. The bridge electrode BE may be disposed under the touch interlayer insulating layer 172 and exposed by two contact holes. Accordingly, the bridge electrode BE may be electrically connected to two adjacent second touch electrodes TE2.

The touch interlayer insulating layer 172 may be disposed on the touch buffer layer 171 so as to cover the bridge electrode BE to insulate the bridge electrode BE from the first touch electrode TE1. In addition, the touch interlayer insulating layer 172 may be disposed between the bridge electrodes BE to insulate the bridge electrodes BE.

The touch interlayer insulating layer 172 may extend to the non-display area NA as well as the display area AA. The touch interlayer insulating layer 172 may cover the dam DAM. For example, the touch interlayer insulating layer 172 may overlap the dam DAM in the vertical (thickness) direction. In this manner, the step difference caused by the dam DAM may be reduced.

The touch buffer layer 171 and the touch interlayer insulating layer 172 may include at least one of an inorganic insulating material, such as silicon nitride (SiNₓ) or silicon oxide (SiOₓ), and an organic insulating material, such as benzocyclobutene (BCB), acrylic resin, epoxy resin, phenolic resin, polyamide resin, or polyimide resin, but are not limited thereto.

A plurality of touch electrodes TE1 and TE2 may be formed on the touch interlayer insulating layer 172. The first touch electrode TE1 may be a touch driving electrode, and the second touch electrode TE2 may be a touch sensing electrode. The first touch electrode TE1 may be electrically connected in a column direction to form a plurality of electrode columns, and the second touch electrode TE2 may be electrically connected in a row direction by the bridge electrode BE to form a plurality of electrode rows.

The outer shapes of the first touch electrode TE1 and the second touch electrode TE2 may have a mesh pattern including a plurality of rhombic shapes, but are not limited thereto. The first touch electrode TE1 and the second touch electrode TE2 may include a metal including at least any one of titanium (Ti), aluminum (Al), molybdenum (Mo), molybdenum titanium (MoTi), copper (Cu), and tantalum (Ta), and may include a transparent conductive material such as indium tin oxide (ITO), indium zinc oxide (IZO), but is not limited thereto.

The plurality of touch electrodes TE1 and TE2 may be disposed in an area corresponding to the bank layer 150. Accordingly, a decrease in light emission efficiency caused by overlap between the plurality of touch electrodes and an emission area may be minimized.

A plurality of pad electrodes PAD may be disposed in the non-display area NA. One end of the plurality of pad electrodes PAD may be electrically connected to the routing line TL, and the other end may be electrically connected to an external circuit such as a touch driver to receive a touch signal from the external circuit or transmit a touch sensing signal to the external circuit.

In this case, a plurality of routing lines TL for electrically connecting the plurality of pad electrodes PAD to the touch electrode TE may be disposed in the non-display area NA.

The routing line TL electrically may connect the plurality of touch electrodes TE to the pad electrode PAD. Specifically, the routing line TL may include a first routing line TL1 connected to the first touch electrode TEL and a second routing line TL2 connected to the second touch electrode TE2. A touch driving signal may be applied to the first touch electrode TE1 through the first routing line TL1 connected to the first touch electrode TE1, and a touch sensing signal may be transmitted to the second touch electrode TE2 through the second routing line TL2 connected to the second touch electrode TE2.

The routing line TL may include a low-resistance metal material, or may include a transparent conductive material such as ITO or IZO, but is not limited thereto. For example, when the plurality of routing lines TL is made of a low-resistance metal material, the resistance may be lowered and the RC delay may be lowered.

Each of the routing lines TL may include a first auxiliary routing line TLa and a second auxiliary routing line TLb. The first auxiliary routing line TLa may be connected to the touch electrode TE disposed in the display area AA and disposed on the touch interlayer insulating layer 172 in the non-display area NA. The second auxiliary routing line TLb may be disposed between the first planarization layer 131 and the second planarization layer 132 of the non-display area NA and connect the first auxiliary routing line TLa and the pad electrode PAD.

The first auxiliary routing line TLa may be electrically connected to the touch sensing unit TS. In this case, the first auxiliary routing line TLa may include the same material as the touch electrode TE of the touch sensing unit TS.

The first auxiliary routing line TLa may be disposed on the touch interlayer insulating layer 172 and may extend from the non-display area NA toward the bending area BA. The first auxiliary routing line TLa may overlap the dam DAM and cover at least a part of the dam DAM. At a point at which the touch interlayer insulating layer 172 ends, the first auxiliary routing line TLa may be disposed on the top surface of the second planarization layer 132.

Meanwhile, the second auxiliary routing line TLb may be disposed in the non-display area NA, and the first auxiliary routing line TLa electrically connecting the second auxiliary routing line TLb and the touch electrode TE may be disposed on the touch interlayer insulating layer 172. The second auxiliary routing line TLb may be electrically connected to the pad electrode PAD to transmit a touch sensing signal sensed by the touch electrode TE to the pad electrode PAD. The second auxiliary routing line TLb may include the same material on the same layer as the connection electrode 138. In particular, the second auxiliary routing line TLb may electrically connect the first auxiliary routing line TLa to the pad electrode PAD and may be disposed between the first planarization layer 131 and the second planarization layer 132.

The first planarization layer 131 and the second planarization layer 132 may be disposed on the substrate 101 throughout the non-display area NA and the display area AA.

In the non-display area NA, the second planarization layer 132 may include a first opening OP1 for contacting the first auxiliary routing line TLa and the second auxiliary routing line TLb. The first auxiliary routing line TLa and the second auxiliary routing line TLb may be in direct contact with or electrically connected to each other through the first opening OP1 of the second planarization layer 132.

A touch planarization layer 173 may be disposed above the plurality of touch electrodes TE to cover upper and side surfaces of the plurality of touch electrodes TE.

The touch planarization layer 173 may cover the plurality of touch electrodes TE, thereby planarizing an upper portion of the plurality of touch electrodes TE. In addition, the touch planarization layer 173 may extend from the display area AA to the non-display area NA, disposed on the first auxiliary routing line TLa in the non-display area NA, and cover the first auxiliary routing line TLa. Accordingly, the touch planarization layer 173 may be inclined from the display area AA to the non-display area NA. In particular, in the non-display area NA, the touch planarization layer 173 may include an inclined surface. The touch planarization layer 173 may cover the touch interlayer insulating layer 172 disposed therebelow, and may cover the dam DAM.

The touch planarization layer 173 may include an organic material having flowability. For example, the touch planarization layer 173 may include, but is not limited to, acryl resin or epoxy resin.

The protective layer 180 may be disposed on the touch planarization layer 173. The protective layer 180 may prevent oxidation, corrosion, or damage to the touch sensing unit TS. The protective layer 180 may cover the touch sensing unit TS. The protective layer 180 may overlap the touch sensing unit TS in a vertical direction (or thickness direction) of the substrate.

Since the protective layer 180 is not restricted by flowability, the protective layer 180 may extend from the display area AA to the non-display area NA to cover the touch planarization layer 173. The protective layer 180 may be disposed on the first opening OP1 included in the second planarization layer 132, and may overlap the first opening OP1 when viewed from a direction perpendicular to the substrate.

The protective layer 180 may include an organic material having flowability. For example, the protective layer 180 may include an organic insulating material such as benzocyclobutene, acrylic resin, epoxy resin, phenolic resin, polyamide resin, or polyimide resin, but is not limited thereto.

The protective layer 180 may be disposed in the first non-display area NA1 without being extended toward the bending area due to the restricted flowability by the lower partition wall adhesive layer 191.

The partition wall adhesive layer 190 may be disposed in the first non-display area NA1. The partition wall adhesive layer 190 may prevent the flow of the touch planarization layer and prevent external moisture from penetrating into the touch sensing unit TS. The partition wall adhesive layer 190 may be disposed in a closed curve shape surrounding the dam DAM in the first non-display area NA1. The partition wall adhesive layer 190 may be disposed adjacent to the bending area BA and may be positioned between the bending area BA and the dam DAM.

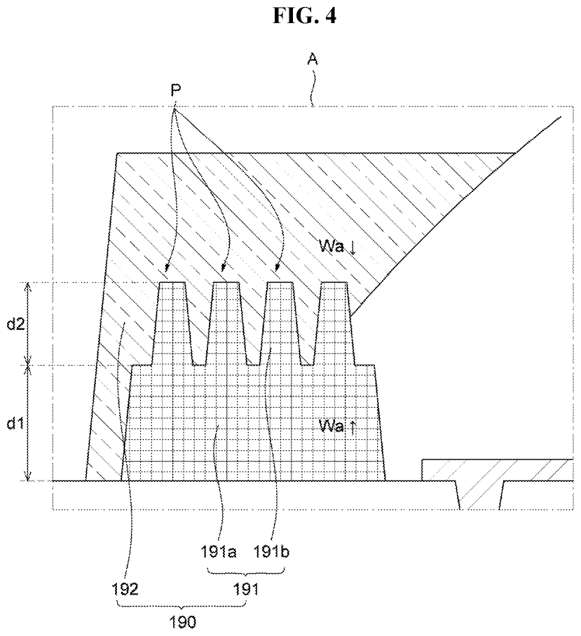

The partition wall adhesive layer 190 may include a lower partition wall adhesive layer 191 and an upper partition wall adhesive layer 192 on the lower partition wall adhesive layer 191. The detailed configuration and effect of the partition wall adhesive layer 190 will be described later with reference to FIG. 4.

The polarization layer POL may be disposed on the protective layer 180 in the display area AA. The polarization layer POL may selectively transmit light to reduce reflection of external light. The polarization layer POL may transmit light oscillating in the same direction as the polarization axis among light emitted from the display unit including the light emitting element 140, and absorb or reflect light oscillating in other directions.

The micro coating layer MCL may be disposed in the bending area BA. In this case, the micro coating layer MCL may overlap at least a portion of the first non-display area NA1 and the second non-display area NA2. For example, the micro coating layer MCL may extend toward the display area AA to contact with one side of the polarization layer POL to be disposed in the first non-display area NA1.

The micro coating layer MCL may have a tensile force applied to the line disposed in the bending area BA, which may cause micro-cracks. Therefore, the micro coating layer MCL may protect the line by coating the bent position with a small thickness. In this case, the micro coating layer MCL may include resin, for example, an acrylic material or urethane acrylate, but is not limited thereto.

The micro coating layer MCL may adjust the neutral plane of the bending area BA. The neutral plane may refer to a virtual plane that is not stressed because the compressive force and tensile force applied to the structure cancel each other when the structure is bent. When two or more structures are stacked, a virtual neutral plane may be formed between the structures. When the entire structure is bent in one direction, structures disposed in the bending direction based on the neutral plane may be compressed by bending and thus may be subjected to a compressive force. On the contrary, structures disposed in a direction opposite to the bending direction based on the neutral plane may be stretched by bending and thus may be subjected to tensile force. In general, structures may be more vulnerable when subjected to tensile force among the same compressive force and tensile force, so cracks are more likely to occur when subjected to tensile force.

Since the line disposed below the neutral plane is compressed, the line may be subjected to a compressive force, and the link line LNK disposed above may be subjected to a tensile force, which may cause cracks due to the tensile force. Accordingly, in order to minimize the tensile force applied to the link line LNK, the micro coating layer MCL may be positioned on the neutral plane.

By disposing the micro coating layer MCL on the bending area BA, the neutral plane may be raised upward, and the neutral plane may be formed at the same position as the line or positioned higher than the line, so that it is not subjected to stress or is subjected to compressive force during bending, thereby suppressing the occurrence of cracks. The elastic modulus of the micro coating layer MCL may be about 50 MPa to about 200 MPa.

Hereinafter, a detailed configuration and effect of the partition wall adhesive layer 190 in the display device according to an embodiment of the present disclosure will be described with reference to FIG. 4.

FIG. 4 is an enlarged schematic cross-sectional view of an area A of FIG. 3. In FIG. 4, the partition wall adhesive layer 190 and the protective layer 180 in contact with the partition wall adhesive layer 190 are specifically illustrated.

The partition wall adhesive layer 190 may include a lower partition wall adhesive layer 191 and an upper partition wall adhesive layer 192 on the lower partition wall adhesive layer 191.

The lower partition wall adhesive layer 191 may reduce bending stress during bending of the display device and prevent cracks from occurring due to bending. The lower partition wall adhesive layer 191 may be disposed in the first non-display area NA1 so as to be adjacent to the bending area BA. The lower partition wall adhesive layer 191 may be positioned between the bending area BA and the dam DAM. The lower partition wall adhesive layer 191 may be disposed on the second planarization layer 132 in the first non-display area NA1 and overlap the second auxiliary routing line TLb. In addition, the lower partition wall adhesive layer 191 may be disposed between the bending area BA and the first opening OP1 so as not to overlap the first opening OP1 to which the first auxiliary routing line TLa and the second auxiliary routing line TLb are connected, but is not limited thereto.

The lower partition wall adhesive layer 191 may include the same material on the same layer as the touch planarization layer 173. However, the thickness d1 of the lower partition wall adhesive layer 191 may be the same as the touch planarization layer 173 or may be thicker than the touch planarization layer 173.

The lower partition wall adhesive layer 191 may prevent the protective layer 180 from flowing to the bending area BA. Accordingly, at least a portion of the inner surface of the lower partition wall adhesive layer 191 may be in direct contact with the protective layer 180.

The lower partition wall adhesive layer 191 may include a lower layer 191a disposed on the second planarization layer 132, and a plurality of protrusion portions 191b disposed on the lower layer 191a and protruding upward.

Specifically, referring to FIG. 4, the lower layer 191a of the lower partition wall adhesive layer 191 may be disposed on the second planarization layer 132 of the first non-display area NA1. The lower layer 191a may be disposed adjacent to the bending area BA and may be positioned between the bending area BA and the dam DAM.

The thickness d1 of the lower layer 191a may be the same as that of the touch planarization layer 173, but is not limited thereto. The thickness d1 of the lower layer 191a may be smaller or larger than the thickness of the touch planarization layer 173 depending on the material of the protective layer 180 or the degree of flow control.

The protrusion portion 191b of the lower partition wall adhesive layer 191 may control the flow of the protective layer 180 and accommodate some materials. The protrusion portion 191b may prevent the flow of the protective layer 180 so that the protective layer 180 does not invade from the display area AA to the bending area BA. In this case, as the plurality of protrusion portions 191b is configured, an accommodation space of the protective layer 180 may be secured. Specifically, when the protective layer 180 is coated more than a predetermined amount or has a large flow property, the protective layer 180 may be passed over the lower partition wall adhesive layer 191 to the bending area BA. In this case, as the plurality of protrusion portions 191b is configured, the protective layer 180 may be filled in the accommodation space provided between the plurality of protrusion portions 191b so that the flowability may be greatly controlled.

Further, the plurality of protrusion portions 191b may effectively improve an adhesive force with the upper partition wall adhesive layer 192. The contact area between the lower partition wall adhesive layer 191 and the upper partition wall adhesive layer 192 may be increased by the plurality of protrusion portions 191b so that the coupling between the lower partition wall adhesive layer 191 and the upper partition wall adhesive layer 192 is improved. Accordingly, separation or detachment between the lower partition wall adhesive layer 191 and the upper partition wall adhesive layer 192 caused by stress generated during bending may be prevented, and penetration of moisture or hydrogen may be reduced.

The protrusion portion 191b may be disposed on the top surface of the lower layer 191a and may have a structure that protrudes long in the upward direction. The protrusion portion 191b may be composed of a plurality of protrusion portions to form a plurality of uneven patterns. FIG. 4 illustrates that four protrusion portions 191b are provided, but not limited thereto.

The protrusion portion 191b may have a polygonal shape, such as a rectangular cross section or a trapezoidal shape in which a side portion has a taper at a predetermined angle. Referring to the enlarged view of FIG. 2, the protrusion portion 191b may have an elongated shape along a direction in which the lower partition wall adhesive layer 191 extends, in particular, the protrusion portion 191b may have a polygonal shape, such as a rectangular shape or a trapezoidal shape, when viewed from the top (or in a plan view), but is not limited thereto. For example, the protrusion portion 191b may be formed in a grid shape when viewed from the top.

The thickness d2 of the protrusion portion 191b may be adjusted to various thicknesses according to the material of the protective layer 180 or the degree of flow control. Further, the interval between the plurality of protrusion portions 191b may be so formed as to provide a space capable of accommodating a part of the protective layer 180 overlapping the lower partition wall adhesive layer 191.

The lower layer 191a and the protrusion portion 191b of the lower partition wall adhesive layer 191 may be integrally formed of the same material. The lower partition wall adhesive layer 191 may be formed through the same process as the touch planarization layer 173. A detailed method of manufacturing the lower partition wall adhesive layer 191 will be described later.

The lower partition wall adhesive layer 191 may relieve bending stress and improve adhesive force to the lower layer 191a so as to prevent cracks during bending and suppress moisture from penetrating into the touch sensing unit TS due to cracks or peeling to corrode the touch electrode TE. To this end, the lower partition wall adhesive layer 191 may have a high adhesive force or a work of adhesion (Wa). Specifically, the lower partition wall adhesive layer 191 may have a work of adhesion higher than that of the upper partition wall adhesive layer 192.

The work of adhesion Wa as used herein may refer to an energy per unit area required to completely separate an interface of two materials in contact with each other into two independent surfaces. For example, the work of adhesion Wa of the lower partition wall adhesive layer 191 may be an adhesion energy between the lower partition wall adhesive layer 191 and the second planarization layer 132 in contact with the lower partition wall adhesive layer 191. In this case, the work of adhesion Wa between the lower partition wall adhesive layer 191 formed of a polymer material and an organic material and the second planarization layer 132, which is a lower layer, may be defined by Equation 1 below using a component-wise harmonic mean of surface free energies of the two materials.

$${W}_{a} = \frac{4 {γ}_{1}^{d} {γ}_{2}^{d}}{{γ}_{1}^{d} + {γ}_{2}^{d}} + \frac{4 {γ}_{1}^{p} {γ}_{2}^{p}}{{γ}_{1}^{p} + {γ}_{2}^{p}} \qquad [ Equation 1 ]$$

In Equation 1, γ₁^{d} and γ₁^{p} represent a dispersion term and a polar term among the surface free energy of a first material (e.g., the lower partition wall adhesive layer 191), respectively. In addition, γ₂^{d} and γ₂^{p} represent a dispersion term and a polar term among the surface free energy of a second material (e.g., the second planarization layer 132), respectively.

In particular, the work of adhesion Wa according to an embodiment of the present disclosure is a derived value obtained by summing binding energies between non-polar (dispersion force) interaction components and binding energies between polar interaction components of each polymer and organic material constituting the layers. As the value of the work of adhesion Wa calculated through Equation 1 increases, the chemical and physical affinity between the lower partition wall adhesive layer 191 and the second planarization layer 132 may increase, which means that the interfacial bonding force is excellent, and thus, peeling between the layers may be effectively prevented even in an environment subjected to repetitive bending stress.

For example, the work of adhesion Wa of the lower partition wall adhesive layer 191 may be about 60 mJ/m² or more, about 70 mJ/m² or more, or about 60 mJ/m² to about 80 mJ/m², but is not limited thereto. When the work of adhesion of the lower partition wall adhesive layer 191 satisfies the upper range, occurrence of cracks in the organic material layer during bending can be suppressed, thereby suppressing penetration of moisture and hydrogen and preventing separation from the lower layer 191a.

Further, an elastic modulus of the lower partition wall adhesive layer 191 may be about 1 GPa to about 3 GPa or about 1.5 GPa to about 2.0 GPa. The hardness of the lower partition wall adhesive layer 191 may be about 0.1 GPa to about 0.25 GPa or about 0.15 GPa to about 0.20 GPa. Further, the water contact angle of the lower partition wall adhesive layer 191 may be about 90 degrees or less or about 60 to about 80 degrees, and the surface energy may be about 30 mN/m or more or about 35 to about 50 mN/m. When the lower partition wall adhesive layer 191 satisfies the above physical property range, the bending stress applied to the adjacent area during the bending of the bending area BA may be reduced, and the crack of the organic layers may be prevented. In addition, adhesion to the lower second planarization layer 132 may be improved.

In a configuration satisfying the physical properties, the lower partition wall adhesive layer 191 may include a silicon-modified polyimide resin having a low coefficient of thermal expansion. In particular, the lower partition wall adhesive layer 191 may be formed from a composition comprising a silicon-modified polyimide resin having a low coefficient of thermal expansion, a low molecular weight monomer, and a plasticizer in order to ensure excellent adhesion to an interface as a reactant.

For example, as the low-molecular monomer, 2-hydroxyethylacrylate, isobornylacrylate, tris(2-hydroxyethyl) isocyanurate diacrylate, butyrate hydroxyanisole, 2,6-di-tert-butyl-4-hydroxymethylphenol, butyrate hydroxytoluene, propylgallate, lauryl gallate, octyl gallate, 2,4,5-trihydroxybutyrophenone, tert-butylhydroquinone 3-aminophenol, 4-aminophenol, 4-methoxyphenol, 2,3,4-trimethylphenol, 2,6-dimethylphenol, poly(4-vinylphenol), and 4-bromophenol may be used. In addition, in order to lower the elastic modulus and the elongation, DOP (dioctyl phthalate), DOA (dioctyl adipate), TCP (tricresyl phosphate), and the like may be used as plasticizers.

The upper partition wall adhesive layer 192 may be disposed on the lower partition wall adhesive layer 191. The upper partition wall adhesive layer 192 may be disposed on the lower partition wall adhesive layer 191 in the first non-display area NA1 to cover the lower partition wall adhesive layer 191. For example, the upper partition wall adhesive layer 192 may be disposed to be in contact with the top surface and the side surface of the lower partition wall adhesive layer 191. In addition, the upper partition wall adhesive layer 192 may be filled between the protrusion portions 191b of the lower partition wall adhesive layer 191 to cover both the side and top surfaces of the protrusion portions 191b.

The upper partition wall adhesive layer 192 may be disposed to be in direct contact with the protective layer 180. The protective layer 180 may be disposed to contact the inner portion of the lower partition wall adhesive layer 191 by lowering the flow by the lower partition wall adhesive layer 191.

Meanwhile, the upper partition wall adhesive layer 192 may be formed on the lower partition wall adhesive layer 191 after forming the protective layer 180. In this case, the upper partition wall adhesive layer 192 may be disposed to simultaneously contact the lower partition wall adhesive layer 191 and the protective layer 180. For example, the upper partition wall adhesive layer 192 may be disposed on the top surface of the lower partition wall adhesive layer 191 and extend to be disposed on a part of the top surface of the adjacent touch planarization layer 173. Further, the upper partition wall adhesive layer 192 may be simultaneously disposed on the top surfaces of the lower partition wall adhesive layer 191 and the protective layer 180. For example, when the protective layer 180 is partially disposed in the accommodation space between the top surfaces of the plurality of protrusion portions 191b of the lower partition wall adhesive layer 191 and the protrusion portions 191b, the upper partition wall adhesive layer 192 may be disposed on the protrusion portions 191b of the lower partition wall adhesive layer 191 and overlap the protective layer 180 filled in the accommodation space between the protrusion portions 191b. In particular, the protective layer 180 may be partially interposed between the upper partition wall adhesive layer 192 and the lower partition wall adhesive layer 191.

The upper partition wall adhesive layer 192 may prevent moisture and hydrogen from penetrating into the touch sensing unit TS from the outside, thereby suppressing the occurrence of cracks during bending. To this end, the upper partition wall adhesive layer 192 may have superhydrophobicity and low work of adhesion. Specifically, the upper partition wall adhesive layer 192 may have a work of adhesion lower than that of the lower partition wall adhesive layer 191. For example, the work of adhesion Wa of the upper partition wall adhesive layer 192 may be about 60 mJ/m² or less, about 50 mJ/m² or less, or about 30 mJ/m² to about 50 mJ/m².

Further, an elastic modulus of the upper partition wall adhesive layer 192 may be about 5 GPa or more or about 6 GPa to about 8 GPa. The hardness of the upper partition wall adhesive layer 192 may be about 0.2 GPa or more or about 0.2 GPa to about 0.3 GPa. Further, the water contact angle of the lower partition wall adhesive layer 191 may be about 90 degrees or more or about 90 degrees to about 110 degrees, and the surface energy may be about 20 mN/m or less or about 20 mN/m to about 30 mN/m.

The upper partition wall adhesive layer 192 may utilize a material that reduces adhesion, so that a superhydrophobic material prevents swelling due to the use of Di Water Rinse that occurs during the photo process. For example, the upper partition wall adhesive layer 192 may include a glass-like material such as a fluorine-based polymer, polysilazane, or polycarbosilane.

In a configuration satisfying the physical properties, the upper partition wall adhesive layer 192 may be formed from a composition including a binder resin, a monomer, and a plasticizer as a reactant.

For example, as the binder resin, an acrylic resin and a siloxane resin may be used. Further, as the monomer, it may be used from 1,6-hexanediol diacrylate, neopentyl glycol diacrylate, ethylene glycol diacrylate, propylene glycol dimethacrylate, pentaerythritol tetraacrylate, pentaerythritol diacrylate, pentaerythritol triacrylate, dipentaerythritol triacrylate, dipentaerythritol pentaacrylate, dipentaerythritol diacrylate, and trimethylpropane triacrylate. Fluoropolymer, polysilazane, polycarbosilane, and the like may be used as the glass-like material.

In a display device including a touch sensor unit for forming a touch electrode on an encapsulation layer for protecting a display element, in the related art, in order to protect the touch electrode or prevent damage to the lower portion when the touch electrode is formed, a protective layer may be disposed below and/or above the touch electrode. However, when the bending area of the display device is bent, moisture and moisture permeate due to cracks generated in the protective layer of the touch electrode, and a problem of deteriorating touch performance and generating stains on the display panel may occur.

According to an embodiment of the present disclosure, a display device may include a partition wall adhesive layer which includes an organic material and has a large work of adhesion and an upper layer having a small work of adhesion so as not to move to a bending area by suppressing a flow of a protective layer.

The lower adhesive layer of the partition wall adhesive layer may be formed on the same layer as the planarization layer on the touch electrode, and the bending stress may be relieved during the bending of the display device through the large work of adhesion, thereby preventing cracks or peeling generated in the organic material layer of the touch sensing unit. In addition, the superhydrophobic upper layer having a small work of adhesion may cover the lower portion and a part of the touch protection layer, thereby suppressing the penetration of moisture from the outside and finally preventing the corrosion and damage of the touch electrode.

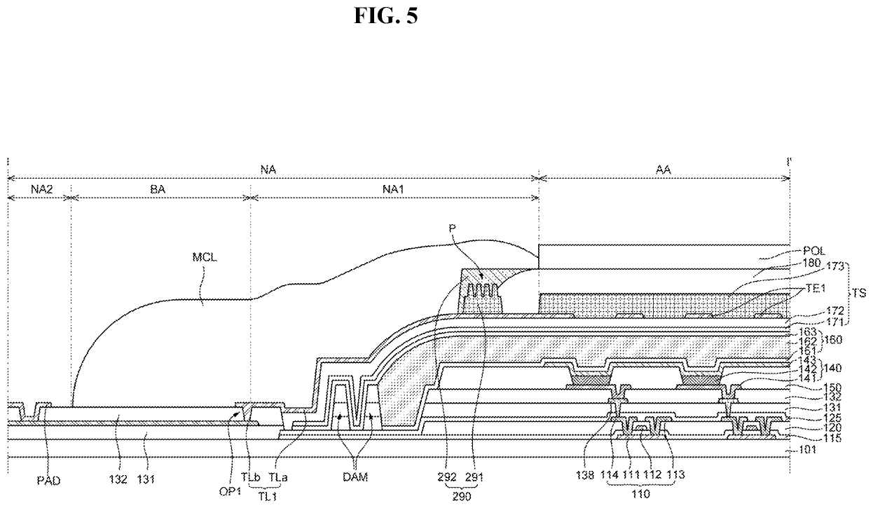

Hereinafter, a display device according to another embodiment of the present disclosure will be described with reference to FIG. 5.

FIG. 5 is a schematic cross-sectional view of a display device according to another embodiment of the present disclosure.

The display device 200 illustrated in FIG. 5 is substantially the same as the display device illustrated in FIGS. 1, 2, 3, and 4 except that the positions at which the partition wall adhesive layer 290 may be disposed are different, so that a redundant description will be omitted.

Referring to FIG. 5, the partition wall adhesive layer 290 may be disposed in the first non-display area NA1 so as to be closer to the display area AA than the bending area BA. At this time, the partition wall adhesive layer 290 may be disposed more adjacent to the display area AA than the dam DAM in the first non-display area NA1. Thus, when viewed from the top, the dam DAM may be disposed to surround the partition wall adhesive layer 290.

As the encapsulation part 160 which is positioned below the partition wall adhesive layer 290 may be positioned more adjacent to the display area AA than the area forming the inclined surface toward the dam DAM, the bending stress applied to the protective layer 180 during the bending of the bending area BA is reduced to suppress the crack and reduce the moisture penetration from the side surface.

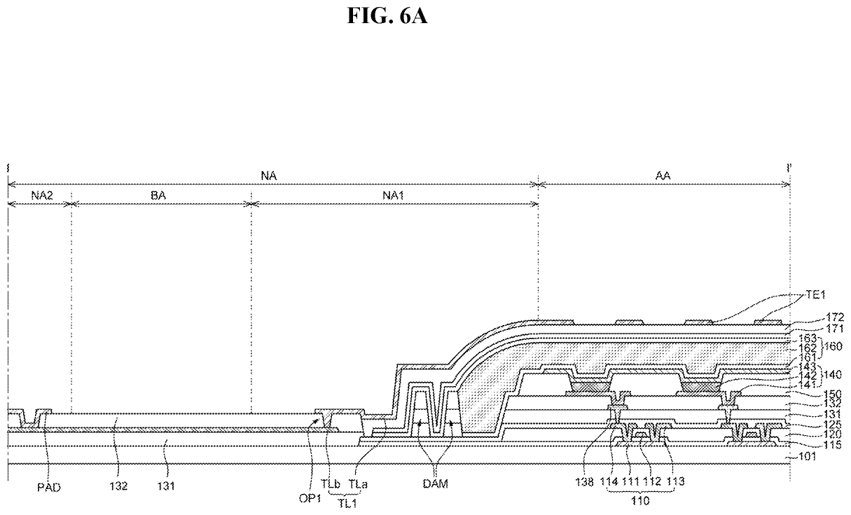

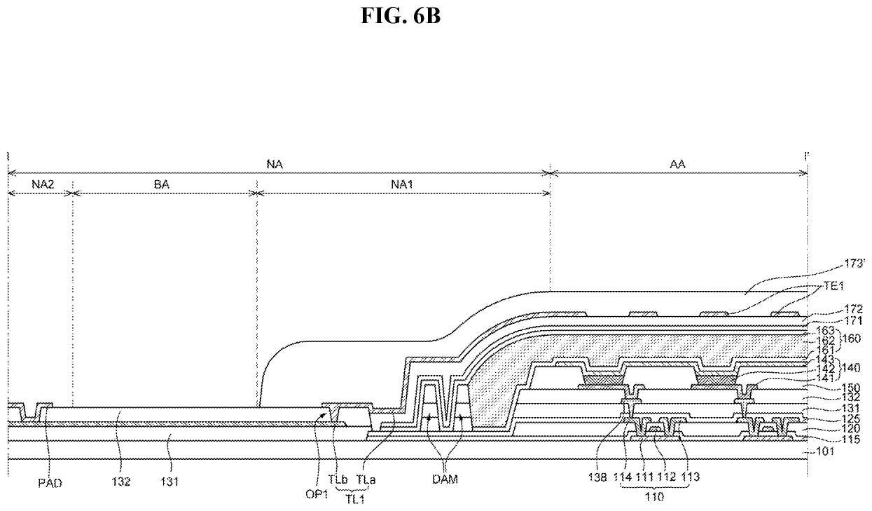

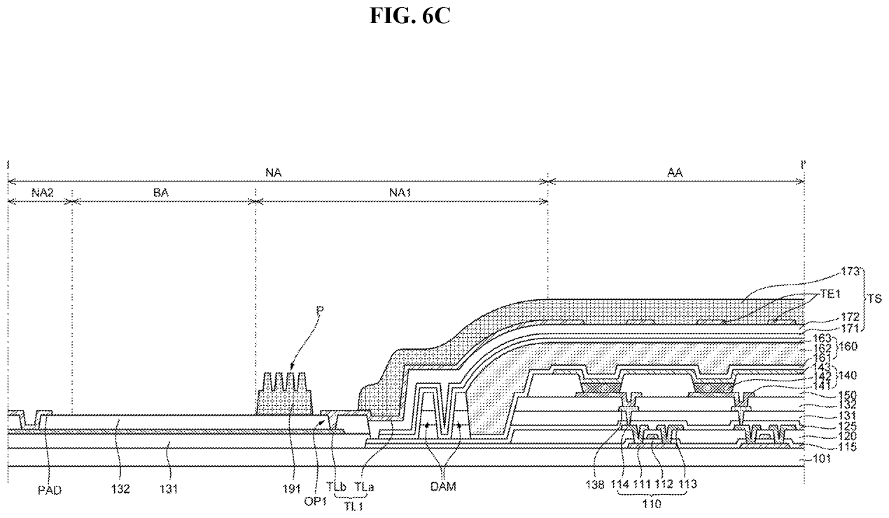

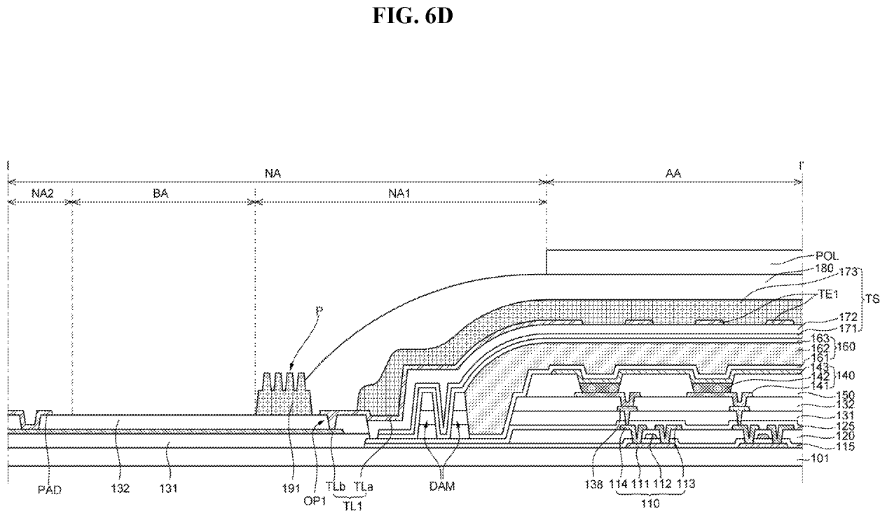

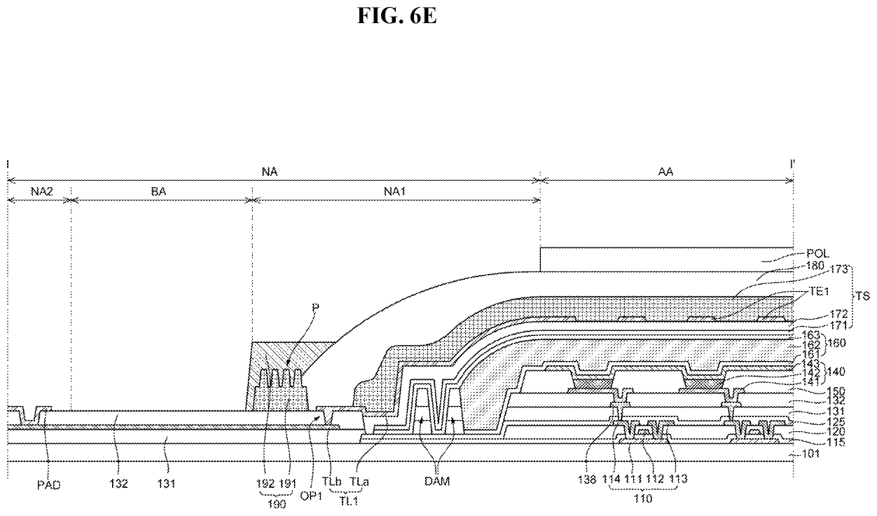

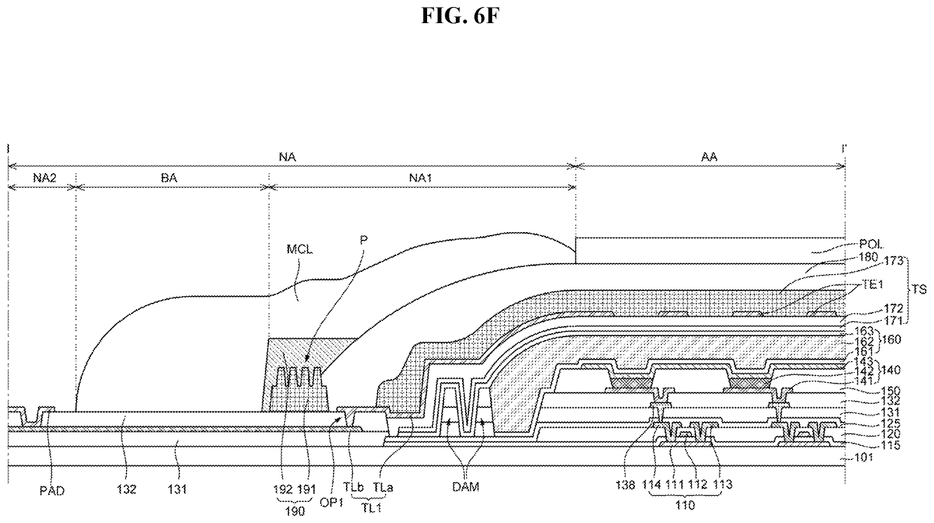

Hereinafter, a method of manufacturing a display device according to an embodiment of the present disclosure will be described with reference to FIGS. 6A, 6B, 6C, 6D, 6E, and 6F.

FIGS. 6A, 6B, 6C, 6D, 6E, and 6F are schematic cross-sectional views for explaining a method of manufacturing a display device according to an embodiment of the present disclosure.

Referring to FIG. 6A, the thin film transistor 110, the light emitting element 140, and the encapsulation part 160 may be formed on the substrate 101. At the same time, the dam DAM, the first planarization layer 131, the second auxiliary routing line TLb, the second planarization layer 132, and the pad electrode PAD may be formed in the non-display area NA. In this case, the first planarization layer 131 and the second planarization layer 132 of the non-display area NA may be formed of (or include) the same material as the first planarization layer 131 and the second planarization layer 132 of the display area AA by the same process. In addition, the second auxiliary routing line TLb may be formed of (or include) the same material as the connection electrode 138 of the display area AA by the same process.

The first opening OP1 may be formed in the second planarization layer 132 of the non-display area NA through a mask process. Accordingly, the second auxiliary routing line TLb below the second planarization layer 132 may be exposed.

The touch sensing unit TS may be formed on the encapsulation part 160. Specifically, the touch buffer layer 171, the bridge electrode BE, the touch interlayer insulating layer 172, and the plurality of touch electrodes TE may be sequentially formed on the encapsulation part 160. In this case, the first auxiliary routing line TLa may include the same material as the touch electrode TE by the same process. By this process, the first auxiliary routing line TLa may be formed from the non-display area NA to the first opening OP1 formed in the second planarization layer 132 adjacent to the bending area. In this case, the pad electrode PAD of the second non-display area NA2 may also be formed by the same process.

Referring to FIG. 6B, in order to form the touch planarization layer 173, the touch protection coating layer 173′ may be applied on the touch electrode TE and the touch interlayer insulating layer 172. In FIG. 6B, the touch protection coating layer 173′ may be applied to be disposed in the display area AA and the first non-display area NA1, but the touch protection coating layer 173′ may be applied to the front surface of the display device. In this case, the touch protection coating layer 173′ may include a photosensitive resin composition.

Referring to FIG. 6C, the touch planarization layer 173 and the lower partition wall adhesive layer 191 may be formed through a photoresist process. For example, the pattern P of the touch planarization layer 173 and the lower partition wall adhesive layer 191 may be simultaneously formed using a halftone mask.

The halftone mask may be composed of masks having different amounts of light transmitted. The halftone mask may include a transmissive area, a blocking area, and a transflective area. The blocking area may be disposed to correspond to the protruding pattern of the lower partition wall adhesive layer 191. The semi-transmissive area may be disposed to correspond to a concave area between the protruding patterns of the touch planarization layer 173 and the lower partition wall adhesive layer 191. The transmissive area may be an area in which the touch protection coating layer 173′ is to be removed, and for example, may be disposed in the first non-display area NA1 so as to correspond to a space between the touch planarization layer 173 and the lower partition wall adhesive layer 191.

The exposure and development process may be performed through a halftone mask. When the composition of the touch protection coating layer 173′ is a positive photoresist, materials in the transmissive area and the semi-transmissive area where light is exposed may be removed by reacting with a developer. Therefore, in response to the semi-transmissive area, only a part of the touch protection coating layer 173′ corresponding to a concave area between the protruding patterns of the touch planarization layer 173 and the lower partition wall adhesive layer 191 may be removed. Accordingly, a portion of the touch protection coating layer 173′ that is not removed may form the pattern P of the protrusion portion 191b of the lower partition wall adhesive layer 191.

Referring to FIG. 6D, a protective layer 180 may be formed on the touch planarization layer 173. The protective layer 180 may be applied to be disposed in the display area AA and the first non-display area NA1. However, the protective layer 180 may be formed to be lower than the thickness of the lower partition wall adhesive layer 191, and one side of the protective layer 180 may be in contact with the side portion of the lower partition wall adhesive layer 191.

Referring to FIG. 6E, an upper partition wall adhesive layer 192 may be formed on the lower partition wall adhesive layer 191. The upper partition wall adhesive layer 192 may be formed through a photoresist process. The upper partition wall adhesive layer 192 may cover side and top surfaces of the lower partition wall adhesive layer 191 adjacent to the bending area BA and may be disposed to simultaneously cover top surfaces of the protective layer 180 adjacent to the lower partition wall adhesive layer 191.

Referring to FIG. 6F, the polarization layer POL may be disposed on the display area AA, and the micro coating layer MCL may be formed in the non-display area NA.

FIG. 6F illustrates that the polarization film POL is directly disposed on the protective layer 180. However, when the polarization film POL is configured by a polarizer or a polarization film, an adhesive film may be formed between the polarization film POL and the protective layer 180.

The micro coating layer MCL may be formed to correspond to the bending area BA of the non-display area NA. In this case, the micro coating layer MCL may be disposed in a part of the first non-display area NA1 and the second non-display area NA2 adjacent to the bending area BA. The micro coating layer MCL may be disposed to cover the partition wall adhesive layer 190 and the protective layer 180 to protect the components below and prevent moisture and hydrogen from penetrating from the outside, and may be disposed to contact one side surface of the polarization layer POL.

According to embodiments of the present disclosure, when the bezel is bent, the thickness of a conventional upper micro coating layer may be reduced in the bending area and the stress caused by the bending may be reduced through the introduction of a lower micro coating layer.

According to embodiments of the present disclosure, it is possible to reduce the thickness of the bezel area and reduce the radius of curvature of the bending area through a plurality of lower micro coating layers cured through different processes.

According to embodiments of the present disclosure, external shock absorption may be improved through a lower micro coating layer having a different modulus, thereby improving impact resistance.

According to embodiments of the present disclosure, it is possible to adjust the bending shape and maintain the reliability environment and shape during the bending process.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate including a display area and a non-display area;
a plurality of light emitting elements disposed in the display area of the substrate;
an encapsulation part disposed to cover the plurality of light emitting elements;
a touch sensing unit disposed on the encapsulation part and including a plurality of touch electrodes;
a touch planarization layer disposed on the plurality of touch electrodes;
a protective layer disposed on the touch planarization layer;
a lower partition wall adhesive layer disposed in the non-display area so as to surround the display area, the lower partition wall adhesive layer being disposed on the same layer as the touch planarization layer while being spaced apart from the touch planarization layer; and
an upper partition wall adhesive layer disposed on the lower partition wall adhesive layer,
wherein the lower partition wall adhesive layer includes a plurality of protrusion portions protruding upward, and the upper partition wall adhesive layer overlaps the plurality of protrusion portions in a thickness direction.

2. The display device according to claim 1, wherein the protective layer extends from the display area to the non-display area and is disposed so that at least a portion of the protective layer is in direct contact with a side surface of the lower partition wall adhesive layer.

3. The display device according to claim 1, wherein the lower partition wall adhesive layer further includes a lower layer, and the plurality of protrusion portions are disposed on a top surface of the lower layer, and
wherein the protective layer is in direct contact with at least a portion of the plurality of protrusion portions.

4. The display device according to claim 3, wherein the upper partition wall adhesive layer is disposed to cover all the top surfaces and side surfaces of the plurality of protrusion portions and the lower layer.

5. The display device according to claim 3, wherein the upper partition wall adhesive layer is disposed on the lower partition wall adhesive layer and on a top surface of the protective layer so as to cover a contact surface between the protective layer and the lower partition wall adhesive layer.

6. The display device according to claim 1, wherein a work of adhesion of the upper partition wall adhesive layer is less than a work of adhesion of the lower partition wall adhesive layer.

7. The display device according to claim 6, wherein the work of adhesion of the lower partition wall adhesive layer is in a range of about 60 to about 80 mJ/m², and
wherein the work of adhesion of the upper partition wall adhesive layer is in a range of about 30 to about 50 mJ/m².

8. The display device according to claim 1, wherein an elastic modulus of the lower partition wall adhesive layer is in a range of about 1.5 to about 2.0 GPa, and
wherein an elastic modulus of the upper partition wall adhesive layer is in a range of about 6.0 to about 8.0 GPa.

9. The display device according to claim 1, wherein the non-display area includes a first non-display area adjacent to the display area, a bending area extending from the first non-display area, and a second non-display area extending from one side of the bending area, and
wherein the lower partition wall adhesive layer and the upper partition wall adhesive layer are disposed between the bending area and the display area.

10. The display device according to claim 9, wherein the touch sensing unit includes:
a touch buffer layer disposed on the encapsulation part;
a bridge electrode disposed on the touch buffer layer;
a touch interlayer insulating layer disposed on the bridge electrode; and
a touch electrode disposed on the touch interlayer insulating layer, and
wherein the lower partition wall adhesive layer overlaps the touch buffer layer and the touch interlayer insulating layer in a thickness direction.

11. The display device according to claim 10, further comprising a plurality of routing lines connecting the plurality of touch electrodes to a plurality of touch pads disposed in the second non-display area,
wherein the lower partition wall adhesive layer is disposed on the plurality of routing lines.

12. The display device according to claim 10, further comprising at least one dam which is disposed in the non-display area and configured to surround the display area,
wherein the encapsulation part includes a first inorganic encapsulation layer, an organic encapsulation layer disposed on the first inorganic encapsulation layer, and a second inorganic encapsulation layer disposed on the organic encapsulation layer,
wherein the first inorganic encapsulation layer and the second inorganic encapsulation layer are disposed on the dam, and
wherein the upper partition wall adhesive layer and the lower partition wall adhesive layer are disposed between the dam and the display area.

13. The display device according to claim 1, wherein the upper partition wall adhesive layer includes a superhydrophobic material.

14. The display device according to claim 1, wherein the lower partition wall adhesive layer includes a same material as the touch planarization layer.
